(19) United States
(12) Patent Application Publication
(10) Pub. No.: US 2026/0247809 A1
(43) Pub. Date: Aug. 20, 2026

(54) DISPLAY PANEL

(71) Applicant: TCL China Star Optoelectronics Technology Co., Ltd., Shenzhen (CN)

(72) Inventors: Jie LI, Shenzhen (CN); Jianjian YING, Shenzhen (CN); Zhiqiang ZHOU, Shenzhen (CN)

(21) Appl. No.: 17/769,745

(22) PCT Filed: Mar. 24, 2022
(86) PCT No.: PCT/CN2022/082798

§ 371 Date: Nov. 16, 2024

(30) Foreign Application Priority Data
Mar. 18, 2022 (CN) 202210270073.7

(51) Int. Cl. H10K 59/131

(52) U.S. Cl. CPC H10K 59/131

(57) ABSTRACT

A display panel is provided. A facing area of a first clock bus line (CK1) relative to an electrode (101) is larger than a facing area of each of second clock bus lines (CK2) relative to the electrode (101) in the display panel in order to compensate a capacitance between the first clock bus line (CK1) and an adjacent one of the second clock bus lines (CK2), so that differences between the capacitance between the first clock bus line (CK1) and the adjacent second clock bus line (CK2) and a capacitance between adjacent ones of the second clock bus lines (CK2) are reduced.

### TECHNICAL FIELD

The present application relates to a technical field of displays, and particularly to a display panel.

### BACKGROUND

Integrating gate driver circuits on display panels can reduce manufacturing cost and facilitate narrow bezel design of the display panels. However, due to capacitance differences and resistance differences among clock signal bus lines, a problem of dense arrangements of horizontal lines of the display panels arises. Although resistance differences among various clock signal bus lines can be improved by routing, due to a disposition of a first clock signal bus line located only adjacent to a second clock signal bus line, a certain degree of difference exists between a capacitance between the first clock signal bus line and the second clock signal bus line and a capacitance between other clock bus lines. The difference between the capacitance between the first clock signal bus line and the second clock signal bus line and the capacitance between other clock bus lines cannot be improved by routing.

### Technical Problem

Embodiments of the present application provide a display panel to improve capacitance differences among various clock signal bus lines, thus remedying a problem of dense arrangements of horizontal lines of display panels.

### Technical Solutions

The present application provides a display panel, a plurality of gate driver circuits, a first clock bus line and a plurality of second clock bus lines, a plurality of clock signal lines, and an electrode.

The second clock bus lines are located on a side of the first clock bus line away from the gate driver circuits, the first clock bus line and the second clock bus lines extend in a first direction and are arranged in the second direction, and the first direction intersects the second direction. The gate driver circuits are electrically connected to the first clock bus line and the second clock bus lines through the clock signal lines, respectively. The electrode faces the first clock bus line and the second clock bus lines.

A facing area of the first clock bus line relative to the electrode is larger than a facing area of each of the second clock bus relative to the electrode.

Optionally, in some embodiments of the present application, a width of the first clock bus line is greater than a width of each of the second clock bus lines in the second direction.

Optionally, in some embodiments of the present application, the first clock bus line includes a first trunk and a second extending portion extending from the first trunk. Specifically, a length of the first trunk is equal to a length of the second clock bus line in the first direction.

Optionally, in some embodiments of the present application, a width of the first trunk is less than a width of the second extending portion in the second direction

Optionally, in some embodiments of the present application, the second extending portion is located at an end of the first clock bus line.

Optionally, in some embodiments of the present application, the first clock bus line further includes a plurality of first openings, and each of the second clock bus lines further includes a plurality of second openings. Specifically, an orthographic projection area of the first openings of the first clock bus line on the electrode is less than an orthographic projection area of the second openings of each of the second clock bus lines on the electrode.

Optionally, in some embodiments of the present application, the first clock bus line has a same width throughout in the second direction.

Optionally, in some embodiments of the present application, each of the second clock bus lines has a same width throughout in the second direction.

Optionally, in some embodiments of the present application, the display panel further includes a color filter substrate including the electrode.

Optionally, in some embodiments of the present application, the display panel further includes a third clock bus line and a plurality of electrode lines. The second clock bus lines are located between the third clock bus line and the first clock bus line, and the electrode line is located on a side of the third clock bus line away from the second clock bus lines. Specifically, the electrode further faces the third clock bus line, and the facing area of the first clock bus line relative to the electrode is larger than a facing area of the third clock bus line relative to the electrode.

Optionally, in some embodiments of the present application, a width of the third clock bus line is same as a width of each of the second clock bus lines in the second direction.

Optionally, in some embodiments of the present application, the first clock bus line further includes a plurality of first openings, and the third clock bus line further includes a plurality of third openings. An orthographic projection area of the first openings of the first clock bus line on the electrode is less than an orthographic projection area of the third openings of the third clock bus line on the electrode.

Optionally, in some embodiments of the present application, the display panel further includes a third clock bus line. The second clock bus lines are located between the third clock bus line and the first clock bus line. Specifically, the electrode further faces the third clock bus line, and the facing area of the first clock bus line relative to the electrode is equal to a facing area of the third clock bus line relative to the electrode.

Optionally, in some embodiments of the present application, a width of the first clock bus line is same as a width of the third clock bus line in the second direction.

Optionally, in some embodiments of the present application, the third clock bus line includes a third trunk and a fourth extending portion extending from the third trunk, and a length of the third trunk is equal to a length of each of the second clock bus lines In the first direction.

Optionally, in some embodiments of the present application, a width of the third trunk is less than a width of the fourth extending portion in the second direction.

Optionally, in some embodiments of the present application, the first clock bus line further comprises a plurality of first openings, and the third clock bus line further comprises a plurality of third openings, wherein an orthographic projection area of the first openings of the first clock bus line on the electrode is equal to an orthographic projection area of the third openings of the third clock bus line on the electrode.

Optionally, in some embodiments of the present application, the third clock bus line has a same width throughout in the second direction.

Optionally, in some embodiments of the present application, the display panel further includes a light-emitting device including an anode and a cathode. The electrode is disposed in a same layer as the anode or the cathode.

Optionally, in some embodiments of the present application, the display panel further includes a plurality of connecting wires and a plurality of pixel driver circuits. A plurality of the light-emitting devices are electrically connected to the pixel driver circuits through the connecting wires, respectively, and the electrode is disposed in a same layer as one of the connecting wires.

The present application further provides a display device including any of the above-mentioned display panels.

### Beneficial Effects

The present application has advantageous effects as follows: embodiments of the present application provide the display panel, including the first clock bus line and the plurality of second clock bus lines located on a side of the first clock bus line away from the gate driver circuits. The first clock bus line and the second clock bus lines extend in the first direction and are arranged in the second direction. The facing area of the first clock bus line relative to the electrode is larger than the facing area of each of the second clock bus lines relative to the electrode, so that a capacitance between the first clock bus line and the electrode is greater than a capacitance between each of the second clock bus lines and the electrode, thereby compensating a capacitance between the first clock bus line and an adjacent one of the second clock bus lines, so that differences between the capacitance between the first clock bus line and the adjacent second clock bus line and a capacitance between adjacent ones of the second clock bus lines are reduced.

### BRIEF DESCRIPTION OF DRAWINGS

FIGS. 1A to 1D are schematic structural views of a display panel provided by an embodiment of the present application.

FIGS. 2A to 2D are schematic structural views of clock bus lines provided by an embodiment of the present application.

Table 1 is a comparison table of differences between a plurality of the clock bus lines before and after improvement.

### DESCRIPTION OF PREFERRED EMBODIMENTS

In order to make the objectives, technical solutions and effects of the present application clearer and clearer, the present application will be described in further detail below with reference to the accompanying drawings and examples. It should be understood that the specific embodiments described here are only used to illustrate the present application, and are not used to limit the present application.

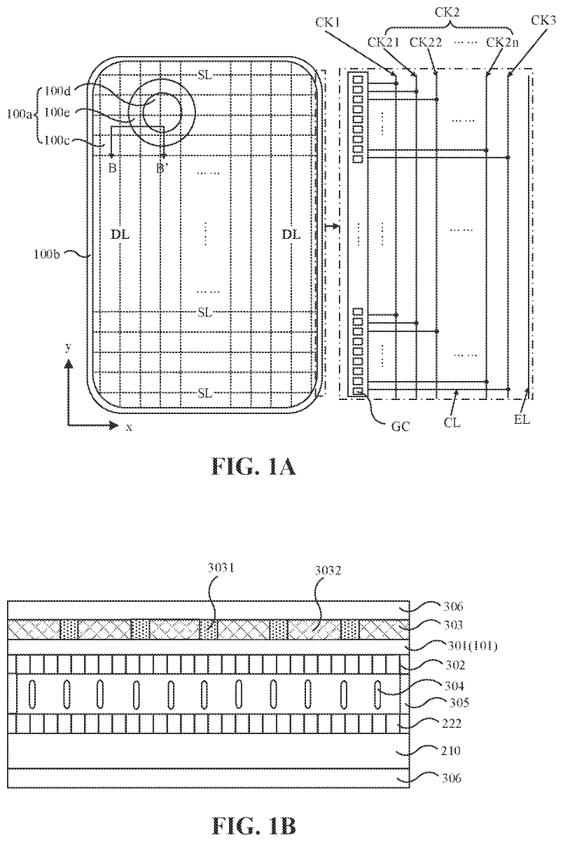

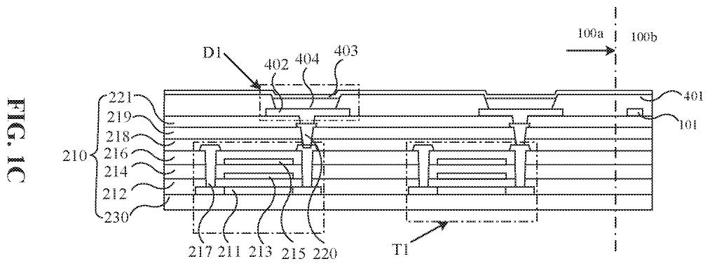

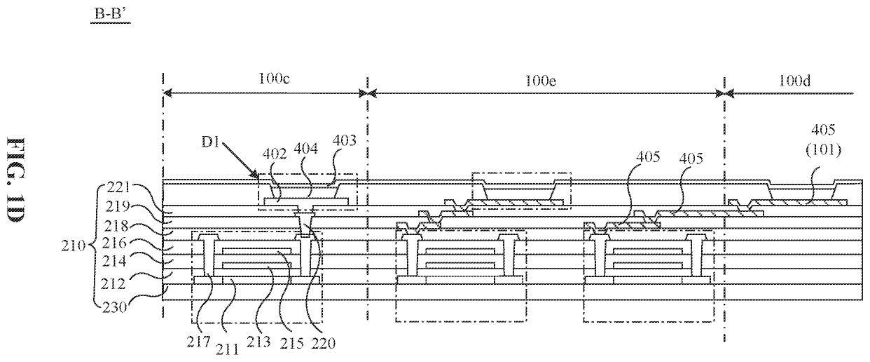

Specifically, FIGS. 1A to 1D are schematic structural views of a display panel provided by an embodiment of the present application. Optionally, the display panel includes a self-luminous display panel and a passive light-emitting display panel. Further, the self-luminous display panel includes a light-emitting device D1. The light-emitting device D1 includes a micro light-emitting diode, a sub-millimeter light-emitting diode, and an organic light-emitting diode. The passive light-emitting display panel includes a liquid crystal display panel, a quantum dot display panel, and the like.

The display panel includes a display area 100a and a non-display area 100b. The display area 100a is configured to achieve a display function. At least one of the display area 100a and the non-display area 100b can implement sensing functions such as imaging, touch, distance, temperature, and the like.

The display panel includes a plurality of data lines DL and a plurality of scan lines SL located in the display area 100a. The data lines DL are arranged in a second direction x, and each of the data lines DL extends in a first direction y. A plurality of scan lines SL are arranged in the first direction y, and each of the scan lines SL extends in the second direction x. The first direction y intersects the second direction x, and the data lines DL and the scan lines SL intersect to form a plurality of subpixels.

The display panel further includes a plurality of gate driver circuits GC, a plurality of clock bus lines, and a plurality of clock signal lines CL located in the non-display area 100b.

The clock bus lines include a first clock bus line CK1, a plurality of second clock bus lines CK2, and a third clock bus line CK3. The second clock bus lines CK2 are located on a side of the first clock bus line CK1 away from the gate driver circuits GC, and the second clock bus lines CK2 are located between the third clock bus line CK3 and the first clock bus line CK1. The first clock bus line CK1, the second clock bus lines CK2, and the third clock bus line CK3 extend in the first direction y and are arranged in the second direction x. The gate driver circuits GC are electrically connected to the first clock bus line CK1, the second clock bus lines CK2, and the third clock bus line CK3 through the clock signal lines CL, respectively.

Further, the data lines DL extend into the non-display area 100b and are electrically connected to a source driver chip located in the non-display area 100b to receive data signals. The scan lines SL extend into the non-display area 100b and are electrically connected to gate driver circuits in the non-display area 100b to receive scan signals.

Optionally, the gate driver circuits GC, the first clock bus line CK1, the second clock bus lines CK2, the third clock bus line CK3, and the clock signal lines CL can be located within a left side border area, and/or a right side border area of the display panel. The source driver chip can be bonded to a lower border area of the display panel in a form of a chip-on-film, so as to realize electrical connection with the data lines DL.

Please continue to refer to FIGS. 1B to 1D. The display panel further includes an electrode 101. The electrode 101 is disposed facing the first clock bus line CK1, the second clock bus lines CK2, and the third clock bus line CK3 to form capacitors with the first clock bus line CK1, the second clock bus lines CK2, and the third clock bus line CK3, respectively.

Specifically, a facing area of the first clock bus line CK1 relative to the electrode 101 is larger than a facing area of each of the second clock bus lines CK2 relative to the electrode 101, so that a capacitance between the first clock bus line CK1 and the electrode 101 is greater than a capacitance between each of the second clock bus lines CK2 and the electrode 101, thereby compensating a capacitance between the first clock bus line CK1 and an adjacent one of the second clock bus lines CK2, so that differences between the capacitance between the first clock bus line CK1 and the adjacent second clock bus line CK2 and a capacitance between adjacent ones of the second clock bus lines CK2 are reduced.

Optionally, by adjusting a length and/or width of the first clock bus line CK1, a facing area of the first clock bus line CK1 relative to the electrode 101 can be made larger than a facing area of each of the second clock bus line CK2 relative to the electrode 101.

In the second direction x, a width of the first clock bus line CK1 is larger than a width of each of the second clock bus lines CK2, so as to increase the facing area of the first clock bus line CK1 relative to the electrode 101, thus increasing a capacitance between the first clock bus line CK1 and the electrode 101, thereby compensating a capacitance between the first clock bus line CK1 and the second clock bus line CK2 adjacent to the first clock bus line CK1, so that differences between the capacitance between the first clock bus line CK1 and the adjacent second clock bus line CK2 and a capacitance between adjacent ones of the second clock bus lines CK2 are reduced.

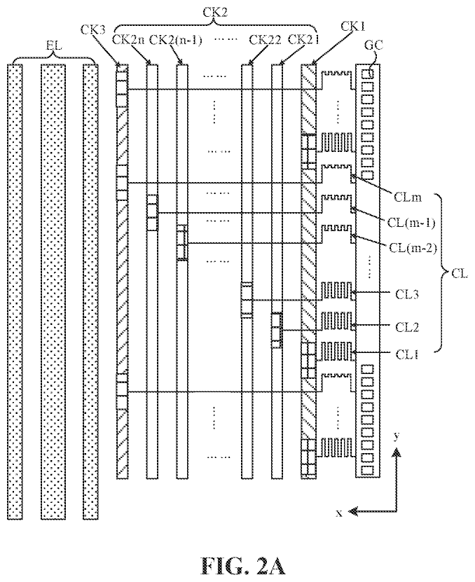

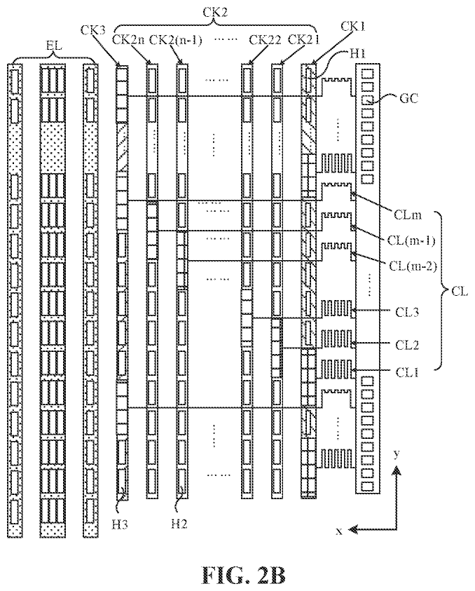

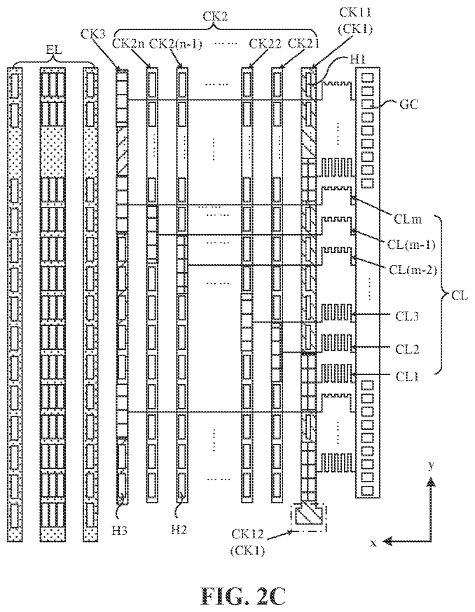

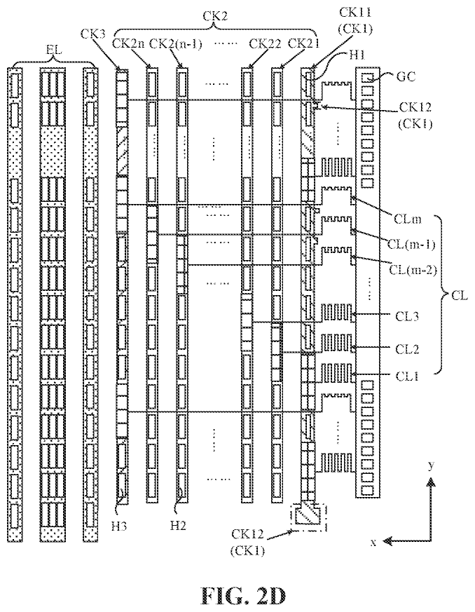

Specifically, referring to FIGS. 2A to 2D showing schematic structural views of the clock bus lines provided by an embodiment of the present application, the second clock bus lines CK2 include a first sub-clock bus line CK21, a second sub-clock bus line CK22, . . . , an n−1^{th} sub-clock bus line CK2(n−1), and a n^{th} sub-clock bus line CK2n. The third clock bus line CK3 is located on a side of the n^{th} sub-clock bus line CK2n away from the n−1^{th} sub-clock bus line CK2(n−1).

The clock signal lines CL include a first clock signal line CL1, a second clock signal line CL2, a third clock signal line CL3, . . . , an m−1^{th} clock signal line CL(m−1), and an m^{th} clock signal line CLm. The first clock signal line CL1 is electrically connected between the first clock bus line CK1 and a corresponding one of the gate driver circuits GC, the second clock signal line CL2 is electrically connected between the first sub-clock bus line CK21 and a corresponding gate driver circuit GC, the third clock signal line CL3 is electrically connected between the second sub-clock bus line CK22 and a corresponding gate driver circuit GC . . . , the m−1^{th} clock signal line CL(m−1) is electrically connected between the n^{th} sub-clock bus line CKn and a corresponding gate driver circuit GC, and the m^{th} clock signal line CLm is electrically connected between the third sub-clock bus line CK3 and a corresponding gate driver circuit GC.

In the second direction x, a width of the first clock bus line CK1 is greater than each of a width of the first sub-clock bus line CK21, a width of the second sub-clock bus line CK22, . . . , a width of the n−1^{th} sub-clock bus line CK2(n−1), and a width of the n^{th} sub-clock bus line CK2n.

The first clock bus line CK1 and the second sub-clock bus line CK22 are arranged on both sides of the first sub-clock bus line CK21. The first sub-clock bus line CK21 and the third sub-clock bus line are arranged on both sides of the second sub-clock bus lines CK22, . . . . The n^{th} sub-clock bus line CK2n and the n−2^{th} sub-clock bus line are arranged on both sides of the n−1^{th} sub-clock bus line CK2(n−1). The n−1^{th} sub-clock bus line CK2(n−1) and the third clock bus line CK3 are arranged on both sides of the n^{th} sub-clock bus line CK2n. The first sub-clock bus line CK21 is only disposed on a side of the first clock bus line CK1 away from the gate driver circuit GC. Therefore, in a conventional display panel design, a capacitance between the first clock bus line CK1 and the first sub-clock bus line CK21 is less than a capacitance between the first sub-clock bus line CK21 and the second sub-clock bus line CK22, a capacitance between the second sub-clock bus line CK22 and the third sub-clock bus line, . . . , a capacitance between the n−1^{th} sub-clock bus line and the n^{th} sub-clock bus line CK2n, and a capacitance between the n^{th} sub-clock bus line CK2n and the third clock bus line CK3. In the present application, by increasing the width of the first clock bus line CK1 in the second direction x, the facing area of the first clock bus line CK1 relative to the electrode 101 can be increased, thereby increasing a capacitance between the first clock bus line CK1 and the electrode 101 and compensating a capacitance between the first clock bus line CK1 and the first sub-clock bus line CK21 adjacent to the first clock bus line CK1, as well as reducing differences between a capacitance between the first clock bus line CK1 and the first sub-clock bus line CK21 and a capacitance between the second sub-clock bus line CK22 and the third sub-clock bus line, . . . , between the n−1^{th} sub-clock bus line and the n^{th} sub-clock bus line CK2n, and between the n^{th} sub-clock bus line CK2n and the third clock bus line CK3, lowering influence of the capacitance differences among the clock bus lines on the gate driver circuits GC, and remedying a problem of a dense arrangement of horizontal lines appearing on the display panel, which in turn is beneficial to achieve the improvement in display quality of the display panel.

Optionally, in the second direction x, the width of the first clock bus line CK1 can be designed by using a current width dimension. By reducing widths of the second clock bus lines CK2, a difference between a capacitance between the first clock bus line CK1 and the adjacent second clock bus line CK2 and a capacitance between adjacent ones of the second clock bus lines CK2 can be reduced.

Although the cost can be saved in the design of reducing the widths of the second clock bus lines CK2 along with a remaining use of the current width of the first clock bus line CK1, the width of each of the second clock bus lines CK2 needs to be adjusted, which is not conducive to simplification of manufacturing processes. For this reason, the widths of the second clock bus lines CK2 can be configured to remain unchanged, while the width of the first clock bus line CK1 is increased to reduce the difference between the capacitance between the first clock bus line CK1 and the adjacent second clock bus line CK2 and the capacitance between adjacent ones of the second clock bus lines CK2.

In addition, the first clock bus line CK1 and the second sub-clock bus line CK22 are arranged on both sides of the first sub-clock bus line CK21. The first sub-clock bus line CK21 and the third sub-clock bus line are arranged on both sides of the second sub-clock bus lines CK22, . . . . The n^{th} sub-clock bus line CK2n and the n−2^{th} sub-clock bus line are arranged on both sides of the n−1^{th} sub-clock bus line CK2(n−1). The n−1^{th} sub-clock bus line CK2(n−1) and the third clock bus line CK3 are arranged on both sides of the n^{th} sub-clock bus line CK2n. In this fashion, a capacitance difference between adjacent ones of the second clock bus lines CK2 is small. Therefore, the widths of the second clock bus lines CK2 in the second direction x are same as each other, thereby reducing difficulty with the manufacturing processes.

Please continue to refer to FIGS. 2A to 2D. The first clock bus line CK1 may have a same width throughout in the second direction x, as shown in FIGS. 2A to 2B. In addition, in an actual product, the gate driver circuits GC, the clock signal lines CL, the clock bus lines and other devices need to be arranged in a narrow space in the non-display area 100b, the first clock bus line CK1, therefore, can also be set in a locally widened manner.

Specifically, as shown in FIGS. 2C to 2D, the first clock bus line CK1 includes a first trunk CK11 and a second extending portion CK12 extending from the first trunk CK11. A length of the first trunk CK11 is equal to a length of the second clock bus line CK2 in the first direction y.

Further, a width of the first trunk CK11 is less than a width of the second extending portion CK12 in the second direction x.

Optionally, the second extending portion CK12 is located at an end of the first clock bus line CK1, as shown in FIG. 2C, to be adapted for a spatial layout in the non-display area 100b of a current display panel. That is, in the non-display area 100b, a device such as a timing controller (not shown) is arranged on upper ends of the clock bus lines, and the gate driver circuits GC are disposed on one side of the clock bus lines close to the display area 100a. Therefore, under a premise of being limited by a space of the non-display area 100b, the second extending portion CK12 can be located at an end of the first clock bus line CK1.

Optionally, the second extending portion CK12 may also be disposed at other positions of the first clock bus line CK1. For example, the second extending portion CK12 is located on a side of the first clock bus line CK1 close to the gate driver circuits GC and is located between any two adjacent clock signal lines CL, as shown in FIG. 2D.

Further, since the clock signal lines CL are electrically connected to the clock bus lines and the gate driver circuits GC, a routing design is adopted to reduce resistance difference. In addition, among the clock signal lines, in a region between the plurality of clock bus lines and the gate driver circuits GS, a routing length of the first clock signal line CL1 connected to the first clock bus line CK1 and a corresponding one of the gate driver circuits GC is greater than a routing length of a clock signal line CLm connected to the third clock bus line CK3 and a corresponding one of the gate driver circuits GC. Therefore, the second extending portion CK12 is located on the side of the first clock bus line CK1 close to the gate driver circuits GC. Further, when located between any adjacent ones of the clock signal lines CL, the second extending portion CK12 may be located between the m^{th} clock signal line CLm electrically connected to the third clock bus line CK3 and a corresponding gate driver circuit GC and the m−1^{th} clock signal line CL(m−1) electrically connected to the n^{th} sub-clock bus line CK2n and a corresponding gate driver circuit GC, or the second extending portion CK12 may be located between the m−1^{th} clock signal line CL(m−1) electrically connected to the n^{th} sub-clock bus line CK2n and a corresponding gate driver circuit GC and an m−2^{th} clock signal line CL(m−2) electrically connected to the n−1^{th} sub-clock bus line CK2(n−1) and a corresponding gate driver circuit GC, as shown in FIG. 2D.

Optionally, the second extending portion CK12 is, but not limited to, polygonal, circular, or semicircular in shape. Optionally, the second extending portions CK12 may be the same or different in shape.

Optionally, a width of the first trunk CK11 in the second direction x may be same as a width of any of the second clock bus lines CK2. Further, each of the second clock bus lines CK2 has a same width throughout in the second direction x, and a width of the first trunk CK11 is same as a width of any of the second clock bus lines CK2, so as to be compatible with a current design and reduce process complexity. That is, in the second direction x, the width of the first trunk CK11 is same as a width of the first sub-clock bus line CK21, the width of the first sub-clock bus line CK21 is same as a width of the second sub-clock bus line CK22, and the width of the second sub-clock bus line CK22 is same as a width of the third sub-clock bus line, . . . , and the width of the n−1^{th} sub-clock bus line CK2(n−1) is same as a width of the n^{th} sub-clock bus line CK2n. Further, a capacitance between the first trunk CK11 and the electrode 101 is equal to a capacitance between the first sub-clock bus line CK21 and the electrode 101, a capacitance between the first sub-clock bus line CK21 and the electrode 101 is equal to a capacitance between the second sub-clock bus line CK22 and the electrode 101, a capacitance between the second sub-clock bus line CK22 and the electrode 101 is equal to a capacitance between the third sub-clock bus line and the electrode 101, . . . , and a capacitance between the n−1^{th} sub-clock bus line CK2(n−1) and the electrode 101 is equal to a capacitance between the n^{th} sub-clock bus line CK2n and the electrode 101.

Specifically, a width of the first clock bus line CK1 can be determined according to whether a capacitance difference between a capacitance formed between the first clock bus line CK1 and the electrode 101 and a capacitance formed between adjacent ones of the second clock bus lines CK2 satisfies design requirements.

Please continue to refer to FIG. 2B. The first clock bus line CK1 further includes a plurality of first openings H1, and each of the second clock bus lines CK2 further includes a plurality of second openings H2. Specifically, an orthographic projection area of the first openings H1 of the first clock bus line CK1 on the electrode 101 is smaller than an orthographic projection area of the second openings H2 of each of the second clock bus lines CK2 on the electrode 101, so that a facing area of the first clock bus line CK1 relative to the electrode 101 is larger than a facing area of each of the second clock bus line CK2 relative to the electrode 101, thereby increasing a capacitance between the first clock bus line CK1 and the electrode 101 and compensating a capacitance between the first clock bus line CK1 and the first sub-clock bus line CK21 adjacent to the first clock bus line CK1, as well as reducing differences between a capacitance between the first clock bus line CK1 and the first sub-clock bus line CK21 and a capacitance between the second sub-clock bus line CK22 and the third sub-clock bus line, . . . , between the n−1^{th} sub-clock bus line and the n^{th} sub-clock bus line CK2n, and between the n^{th} sub-clock bus line CK2n and the third clock bus line CK3, lowering influence of the capacitance differences among the clock bus lines on the gate driver circuits GC, and remedying a problem of a dense arrangement of horizontal lines appearing on the display panel, which in turn is beneficial to achieve the improvement in display quality of the display panel.

Optionally, in the first direction y, a length of each of the first openings H1 may be same or different, and a width of each of the first openings H1 may be same or different.

Optionally, areas of the second openings H2 included in each of the second clock bus lines CK2 may be same or different. In the first direction y, a length of each of the second openings H2 may be same or different, and in the second direction x a width of each of the second openings H2 may be same or different.

Optionally, each of the first openings H1 is, but not limited to, polygonal, circular, diamond-like, wave-like, or semicircular in shape. Optionally, each of the second openings H2 is, but not limited to, polygonal, circular, diamond-like, wave-like, or semicircular in shape.

It can be understood that an area of each of the first openings H1 and an area of each of the second openings H2 can be set according to a capacitance difference between adjacent ones of the clock bus lines. Optionally, the first openings H1 may be located in the first trunk CK1.

Since when the display panel is in actual operation, there will be mutual interference between the clock signal lines CL and the clock bus lines. For this reason, there must be a difference in capacitance between the first clock bus line CK1 and the adjacent second clock bus line CK2. For this reason, the capacitance difference between the first clock bus line CK1 and the adjacent second clock bus line CK2 is limited to be less than or equal to 0.5 picofarads (pf) in order to satisfy design requirements. Those skilled in the art can also reasonably select a limited capacitance difference value according to design requirements.

Please continue to refer to FIGS. 2A to 2D. The display panel further includes electrode lines EL located on a side of the third clock bus line CK3 away from the second clock bus lines CK2.

Since the electrode lines EL and the n^{th} sub-clock bus line CK2n are arranged on both sides of the third clock bus line CK3, a difference between a capacitance between the third clock bus line CK3 and the n^{th} sub-clock bus line CK2n and a capacitance between the second clock bus lines CK2 is small. Therefore, the third clock bus line CK3 and the second clock bus line CK2 can be designed in a similar manner. That is, the facing area of the first clock bus line CK1 relative to the electrode 101 is larger than a facing area of the third clock bus line CK3 relative to the electrode 101. Further, a width of the third clock bus line CK3 may be same as a width of each of the second clock bus lines CK2 in the second direction x, and/or the third clock bus line CK3 includes a plurality of third openings H3, an orthographic projection area of the third openings H3 on the electrode 101 is larger than the orthographic projection area of the first openings H1 on the electrode 101.

Optionally, if there is no electrode line EL on the side of the third clock bus line CK3 away from the second clock bus lines CK2, the third clock bus line CK3 can be configured in a similar manner as the first clock bus line CK1 to improve differences between the capacitance between the third clock bus line CK3 and the n^{th} sub-clock bus line CK2n, and a capacitance between the first clock bus line CK1 and the first sub-clock bus line CK21, between the first sub-clock bus line CK21 and the second sub-clock bus line CK22, . . . , and between the n−1^{th} sub-clock bus line CK2(n−1) and the n^{th} sub-clock bus line CK2n.

Specifically, if there is no electrode line EL on the side of the third clock bus line CK3 away from the second clock bus lines CK2, the facing area of the first clock bus line CK1 relative to the electrode 101 is equal to the facing area of the third clock bus line CK3 relative to the electrode 101.

Further, in the second direction x, the width of the first clock bus line CK1 is same as the width of the third clock bus line CK3.

Further, the third clock bus line CK3 includes a third trunk and a fourth extending portion extending from the third trunk, wherein a width of the third trunk is less than a width of the fourth extending portion In the second direction x. Optionally, the fourth extending portion is located at an end of the third clock bus line CK3. Optionally, a length of the third trunk is equal to a length of the second clock bus line CK2 in the first direction y. Optionally, a length of the first trunk CK11 is equal to a length of the third trunk in the first direction y.

Optionally, the third clock bus line CK3 has a same width throughout in the second direction x.

Optionally, the third clock bus line CK3 includes a plurality of third openings H3. An orthographic projection area of the third openings H3 on the electrode 101 is equal to the orthographic projection area of the first openings H1 included in the first clock bus line CK1 on the electrode 101.

It can be understood that the widths of the first trunk CK11 and the third trunk in the second direction x, sizes and shapes of the second extending portion CK12 and the fourth extending portion, and the orthographic projection areas of the first openings H1 and the third openings H3 on the electrode 101 can be differentially determined according to differences between the capacitance between the first clock bus line CK1 and the second clock bus line adjacent to the first clock bus line CK1 and the capacitance between the third clock bus line CK3 and the second clock bus line adjacent to the third clock bus line CK3.

Please continue to refer to FIGS. 1C to 1D. The display panel further includes an array substrate 210 including a plurality of pixel driver circuits. The pixel driver circuits include at least one transistor T1 and control the subpixels to emit light according to data signals transmitted by the data lines DL and scan signals transmitted by the scan lines SL.

Optionally, the array substrate 210 includes a substrate 230, and an active layer 211, a first gate insulating layer (GI1) 212, a first gate layer (GE1) 213, a second gate insulating layer (GI2) 214, a second gate layer (GE2) 215, a dielectric insulating layer (ILD) 216, a first source/drain layer (SD1) 217, a passivation layer (PV) 218, a first planarization layer (PLN1) 219, a second source/drain layer (SD2) 220, and a second flat layer (PLN2) 221 all located on the substrate 230.

Optionally, the clock signal lines CL are arranged in a same layer as the first gate layer 213, and the clock bus lines are arranged in a same layer as the first source/drain layer 217.

Optionally, please continue to refer to FIG. 1B. The display panel is a liquid crystal display panel and further includes a color filter substrate. The color filter substrate includes a common electrode 301, a first alignment layer 302, and a color filter 303 located on a side of the common electrode 301 away from the first alignment layer 302. Further, the color filter 303 includes a black matrix 3031 and a plurality of color filter units 3032. In order to simplify a process flow, the electrode 101 and the common electrode 301 can be in made a same layer.

It can be understood that the electrode 101 may not be in the same layer as the common electrode 301. That is, an actual position of the electrode 101 can be determined according to a required capacitance formed between the first clock bus line CK1 and the electrode 101.

Further, the display panel further includes a liquid crystal 304, a sealant 305, and a polarizer 306. The liquid crystal 304 and the sealant 305 are located between the array substrate 210 and the color filter substrate. The array substrate 210 further includes a second alignment layer 222.

Optionally, please continue to refer to FIGS. 1C and 1D. The display panel is a self-luminous display panel. The display panel further includes a light-emitting device D1 and a pixel definition layer 401. The light-emitting device D1 includes an anode 402, a cathode 403, and a light-emitting layer 404 located between the anode 402 and the cathode 403. The light-emitting layer 404 is located in a pixel definition area of the pixel definition layer 401. Specifically, the electrode 101 may be disposed in a same layer as the anode 402 or the cathode 403.

Optionally, please continue to refer to FIGS. 1A and 1D. The display area 100a of the display panel includes a main display area 100c, a light-transmitting sensing area 100d, and a transition area 100e located between the main display area 100c and the light-transmitting sensing area 100d. The display panel further includes a sensing device disposed facing the light-transmitting sensing area 100d. The pixel driver circuits for driving the subpixels in the light-transmitting sensing area 100d to emit light are located in the transition area 100e. The subpixels located in the light-transmitting sensing region 100d are electrically connected to the pixel driver circuits through a plurality of connecting wires 405, respectively. Specifically, the connecting wires 405 can be disposed to a same layer or different layers as required. The electrode 101 can be disposed in a same layer as any one of the connecting wires 405, so as to adjust a spacing between the first clock bus line CK1 and the electrode 101 along with the simplification of the process flow, thus adjusting the capacitance between the first clock bus line CK1 and the electrode 101.

Optionally, the sensing device includes a camera, a fingerprint sensor, a distance sensor, and the like.

Optionally, the anode 402 of the light-emitting device D1 can be fabricated by a single-layer process or a multilayer process. Further, the anode 402 of the light-emitting device D1 is made of a material including indium tin oxide or indium tin oxide/silver/indium tin oxide. Optionally, the light-emitting device D1 further includes a hole transport layer, a charge transport layer, and other parts not shown.

Optionally, the electrode 101 is made of a material including indium tin oxide (ITO, In2O3:Sn), aluminum-doped zinc oxide (AZO, ZnO:Al), fluorine-doped tin oxide (FTO, SnO2:F), antimony tin oxide (ATO, Sn2O:Sb) and conductive oxide films (including CdO, In2O3, SnO2 and ZnO, etc.).

Optionally, the display panel further includes parts that are not shown, such as an encapsulation layer, a polarizer, and a touch electrode.

The applicant of the present application has verified capacitance differences between the clock bus lines before and after improvement, and verification results are shown in Table 1.

TABLE 1

| clock bus line | CK1 | CK21 | CK22 | CK23 | CK24 | CK25 |
|---|---|---|---|---|---|---|
| before | 51.3 | 52.4 | 52.3 | 52.5 | 52.6 | 52.7 |
| improvement | | | | | | |
| after | 52.4 | 52.4 | 52.3 | 52.5 | 52.6 | 52.7 |
| improvement | | | | | | |
| clock bus line | CK26 | CK27 | CK28 | CK29 | CK20 | CK3 |
| before | 52.4 | 52.5 | 52.6 | 52.7 | 52.7 | 52.5 |
| improvement | | | | | | |
| after | 52.4 | 52.5 | 52.6 | 52.7 | 52.7 | 52.5 |
| improvement | | | | | | |

Specifically, Table 1 is illustrated according to the structure shown in FIG. 2C. The display panel includes 12 clock bus lines including one first clock bus line CK1, ten second clock bus lines CK2, and one third clock bus line CK3. The first clock bus line CK1 includes the first trunk CK11 and the second extending portion CK12. The width of each of the second clock bus lines CK2 is same throughout in the second direction x. The width of the first trunk CK11 is same as the width of any of the second clock bus lines CK2. The width of the third clock bus line CK3 is same as the width of any of the second clock bus lines CK2. An area of the second extending portion CK12 is 60 microns (μm)×90 μm. The ten second clock bus lines CK2 include a first sub-clock bus line CK21, a second sub-clock bus line CK22, a third sub-clock bus line CK23, a fourth sub-clock bus line CK24, a fifth sub-clock bus line CK25, a sixth sub-clock bus line CK26, a seventh sub-clock bus line CK27, an eighth sub-clock bus line CK28, a ninth sub-clock bus line CK29, and a tenth sub-clock bus line CK20. Capacitance values of each clock bus line measured in Table 1 includes two parts: one is the capacitance between each clock bus line and the electrode, and the other is the capacitance between adjacent ones of the clock bus lines.

As can be seen from Table 1, before the improvement, the first clock bus line CK1 and each of the second clock bus lines CK2 adopt a same design. Therefore, the facing area of the first clock bus line CK1 relative to the electrode 101 is equal to the facing area of each of the second clock bus lines CK2 relative to the electrode 101. Thus, the capacitance between the first clock bus line CK1 and the electrode 101 is equal to the capacitance between each of the second clock bus line CK2 and the electrode 101, and the measured capacitance value is a capacitance difference between adjacent ones of the clock bus lines. That is, before the improvement, a capacitance difference between the first clock bus line CK1 and the first sub-clock bus line CK21 is 1.1 picofarads. After improvement, the difference between the measured capacitance with respect to the first clock bus line CK1 and the measured capacitance with respect to the first sub-clock bus line CK21 is reduced to 0.0289 picofarads which proves that the capacitance difference between the first clock bus line CK1 and the first sub-clock bus line CK21 is significantly reduced after the improvement, thereby remedying the problem of the dense arrangement of horizontal lines appearing on the display panel, which in turn is beneficial to achieve the improvement in display quality of the display panel.

The present application further provides a display device including any of the above-mentioned display panels.

It can be understood that the display device includes a movable display device (such as a notebook computer, a mobile phone, etc.), a fixed terminal (such as a desktop computer, a television, etc.), a measurement device (such as a sports bracelet, a thermometer, etc.), and the like.

Specific embodiments are used herein to illustrate the principles and implementation of the application, and the descriptions of the above embodiments are only intended to help understand the methods and core ideas of the application; In addition, for those skilled in the art, according to the idea of the application, there will be changes in the specific implementation and the scope of application. In summary, the content of this specification should not be construed as a limitation of the application.

What is claimed is:

1. A display panel, comprising:
a plurality of gate driver circuits;
a first clock bus line and a plurality of second clock bus lines located on a side of the first clock bus line away from the gate driver circuits, wherein the first clock bus line and the second clock bus lines extend in a first direction and are arranged in the second direction, and the first direction intersects the second direction;
a plurality of clock signal lines, wherein the gate driver circuits are electrically connected to the first clock bus line and the second clock bus lines through the clock signal lines, respectively; and
an electrode facing the first clock bus line and the second clock bus lines;
wherein a facing area of the first clock bus line relative to the electrode is larger than a facing area of each of the second clock bus relative to the electrode.

2. The display panel of claim 1, wherein a width of the first clock bus line is greater than a width of each of the second clock bus lines in the second direction.

3. The display panel of claim 2, wherein the first clock bus line comprises a first trunk and a second extending portion extending from the first trunk;
wherein a length of the first trunk is equal to a length of the second clock bus line in the first direction.

4. The display panel of claim 3, wherein a width of the first trunk is less than a width of the second extending portion in the second direction.

5. The display panel of claim 3, wherein the second extending portion is located at an end of the first clock bus line.

6. The display panel of claim 1, wherein the first clock bus line further comprises a plurality of first openings, and each of the second clock bus lines further comprises a plurality of second openings;
wherein an orthographic projection area of the first openings of the first clock bus line on the electrode is less than an orthographic projection area of the second openings of each of the second clock bus lines on the electrode.

7. The display panel of claim 1, wherein the first clock bus line has a same width throughout in the second direction.

8. The display panel of claim 1, wherein each of the second clock bus lines has a same width throughout in the second direction.

9. The display panel of claim 1, further comprising a color filter substrate including the electrode.

10. The display panel of claim 1, further comprising a third clock bus line and a plurality of electrode lines, wherein the second clock bus lines are located between the third clock bus line and the first clock bus line, and the electrode line is located on a side of the third clock bus line away from the second clock bus lines;
wherein the electrode further faces the third clock bus line, and the facing area of the first clock bus line relative to the electrode is larger than a facing area of the third clock bus line relative to the electrode.

11. The display panel of claim 10, wherein a width of the third clock bus line is same as a width of each of the second clock bus lines in the second direction.

12. The display panel of claim 10, wherein the first clock bus line further comprises a plurality of first openings, and the third clock bus line further comprises a plurality of third openings;
wherein an orthographic projection area of the first openings of the first clock bus line on the electrode is less than an orthographic projection area of the third openings of the third clock bus line on the electrode.

13. The display panel of claim 1, further comprising a third clock bus line, wherein the second clock bus lines are located between the third clock bus line and the first clock bus line;
wherein the electrode further faces the third clock bus line, and the facing area of the first clock bus line relative to the electrode is equal to a facing area of the third clock bus line relative to the electrode.

14. The display panel of claim 13, wherein a width of the first clock bus line is same as a width of the third clock bus line in the second direction.

15. The display panel of claim 13, wherein the third clock bus line comprises a third trunk and a fourth extending portion extending from the third trunk, and a length of the third trunk is equal to a length of each of the second clock bus lines in the first direction.

16. The display panel of claim 15, wherein a width of the third trunk is less than a width of the fourth extending portion in the second direction.

17. The display panel of claim 13, wherein the first clock bus line further comprises a plurality of first openings, and the third clock bus line further comprises a plurality of third openings, wherein an orthographic projection area of the first openings of the first clock bus line on the electrode is equal to an orthographic projection area of the third openings of the third clock bus line on the electrode.

18. The display panel of claim 13, wherein the third clock bus line has a same width throughout in the second direction.

19. The display panel of claim 1, further comprising a light-emitting device comprising an anode and a cathode, wherein the electrode is disposed in a same layer as the anode or the cathode.

20. The display panel of claim 19, further comprising a plurality of connecting wires and a plurality of pixel driver circuits, wherein a plurality of the light-emitting devices are electrically connected to the pixel driver circuits through the connecting wires, respectively, and the electrode is disposed in a same layer as one of the connecting wires.
